(19) United States
(12) Patent Application Publication
(10) Pub. No.: US 2026/0271780 A1
(43) Pub. Date: Sep. 10, 2026

(54) HYBRID-BOND INTERFACE STRUCTURE INCLUDING MULTIPLE DIELECTRIC LAYERS

(71) Applicant: Micron Technology, Inc., Boise, ID (US)

(72) Inventor: Ying-Tsun Su, Taipei (TW)

(21) Appl. No.: 19/541,312

(22) Filed: Feb. 16, 2026

Related U.S. Application Data
(60) Provisional application No. 63/769,609, filed on Mar. 10, 2025.

(51) Int. Cl. H10W 80/00; H10W 90/00

(52) U.S. Cl. CPC H10W 80/327; H10W 90/792

(57) ABSTRACT

Methods, systems, and devices for hybrid-bond interface structure including multiple dielectric layers are described. In some examples, a stacked die assembly may include a first semiconductor die coupled with a second semiconductor die. The first semiconductor die may include a first dielectric layer that is densified using first impurities introduced to a first matrix material and a first conductive bonding pad in the first dielectric layer. The stacked die assembly may further include a second dielectric layer that is densified using second impurities introduced to a second matrix material. The second dielectric layer may be along a bond interface between the first semiconductor die and the second semiconductor die.

### CROSS REFERENCE

The present Application for Patent claims priority to U.S. Patent Application No. 63/769,609 by Su et al., entitled “HYBRID-BOND INTERFACE STRUCTURE INCLUDING MULTIPLE DIELECTRIC LAYERS,” filed Mar. 10, 2025, which is assigned to the assignee hereof, and which is expressly incorporated by reference in its entirety herein.

### TECHNICAL FIELD

The following relates to one or more systems for memory, including a hybrid-bond interface structure including multiple dielectric layers.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports a hybrid-bond interface structure including multiple dielectric layers in accordance with examples as disclosed herein.

FIG. 2 shows an example implementation that supports a hybrid-bond interface structure including multiple dielectric layers in accordance with examples as disclosed herein.

FIG. 3 shows an example implementation that supports a hybrid-bond interface structure including multiple dielectric layers in accordance with examples as disclosed herein.

FIG. 4 shows an example of a manufacturing system that supports a hybrid-bond interface structure including multiple dielectric layers in accordance with examples as disclosed herein.

FIGS. 5A and 5B show stages of an example manufacturing process that supports a hybrid-bond interface structure including multiple dielectric layers in accordance with examples as disclosed herein.

FIG. 6 shows a flowchart illustrating a method or methods that support hybrid-bond interface structure including multiple dielectric layers in accordance with examples as disclosed herein.

### DETAILED DESCRIPTION

A memory die may be part of a stacked die assembly that includes the memory die coupled with another semiconductor die (e.g., another memory die or a logic die that is coupled with the memory die using die-to-die and/or wafer-to-wafer stacking). A bond interface structure that couples the memory die with the other semiconductor die may be a hybrid-bond interface structure, including a combination of metal-to-metal bonds and dielectric-to-dielectric bonds.

In some cases, imperfect alignment of bonding pads (e.g., metal bonding pads) along the hybrid-bond interface structure may result in portion of the hybrid-bond interface structure having metal-to-metal interface portions, dielectric-to-dielectric interface portions, and metal-to-dielectric interface portions. The metal-to-dielectric interface portions may exacerbate a potential for diffusion and/or migration of metal atoms, molecules, and/or ions from a bonding pad into a dielectric material along the interface, causing an increased risk of electrical shorting and/or leakage in the stacked die assembly.

In accordance with examples as described herein, a stacked die assembly may include a first semiconductor die coupled with a second semiconductor die. The first semiconductor die may include first dielectric layer that is densified using first impurities introduced to a first matrix material and a first conductive bonding pad in the first dielectric layer. The stacked die assembly may further include a second dielectric layer that is densified using second impurities introduced to a second matrix material. The second dielectric layer may be along a bond interface between the first semiconductor die and the second semiconductor die.

The first and second dielectric layers may satisfy one or more dielectric constant (e.g., k-value) thresholds, thereby enabling the stacked die assembly to achieve speed performance targets that may be otherwise compromised by excessive resistance/capacitance (RC) delays. Additionally, or alternatively, the first and second dielectric layers may be doped with impurities that densify at least portions of the first and second dielectric layers to reduce a likelihood of diffusion and/or migration of atoms, molecules, and/or ions from the bonding pad into layers of the stacked die assembly, thereby reducing a likelihood of electrical shorting and/or leakage within the stacked die assembly and improving a performance of the stacked die assembly.

In addition to applicability in memory systems as described herein, a hybrid-bond interface structure including multiple dielectric layers may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds and reducing leakage (or other electrical defects), which may decrease processing or latency times, improve response times, or otherwise improve user experience, among other benefits.

Features of the disclosure are illustrated and described in the context of systems, devices, and circuits. Features of the disclosure are further illustrated and described in the context of an example hybrid-bond interface structure, an example manufacturing system used to fabricate the hybrid-bond interface structure, an example manufacturing process using the manufacturing system, and flowcharts.

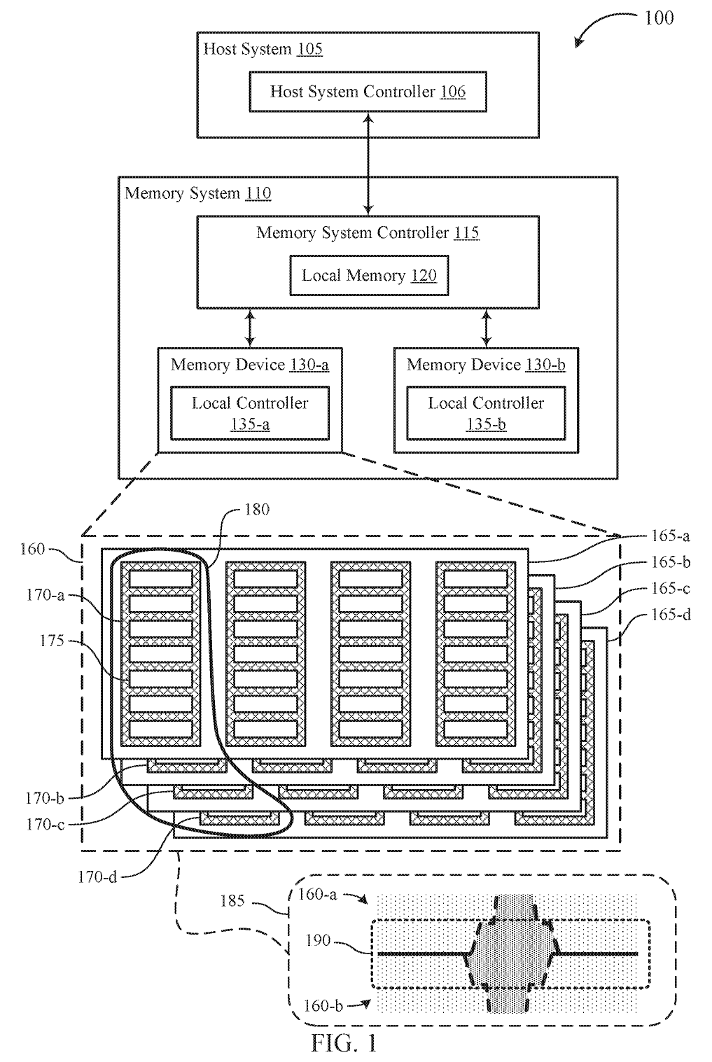

FIG. 1 shows an example of a system 100 that supports a hybrid-bond interface structure including multiple dielectric layers in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a,170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

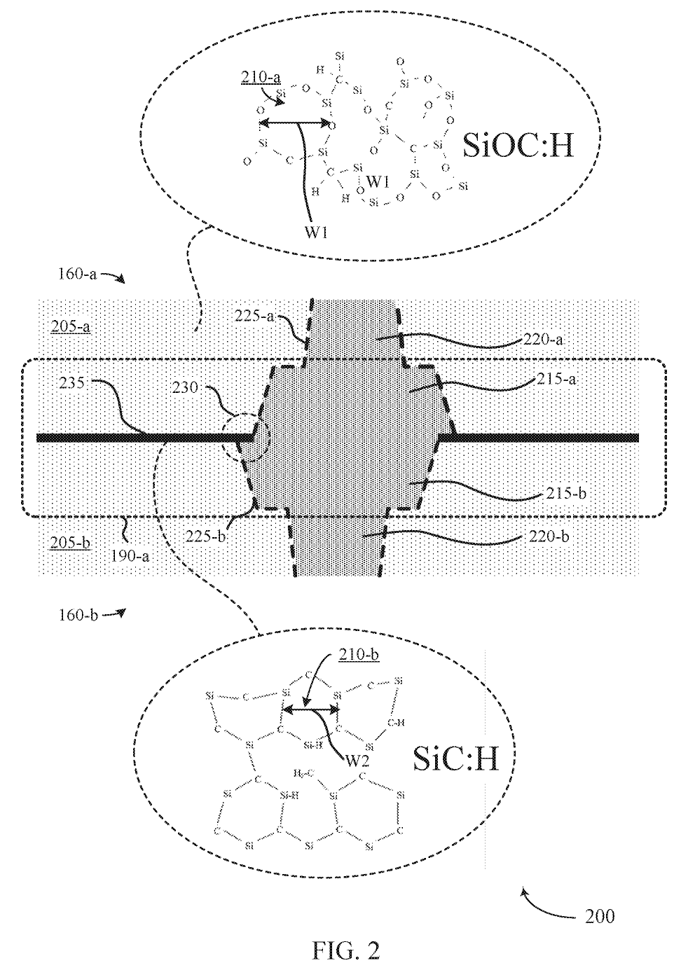

In some examples, and as described herein, a memory device 130 may include one or more dies 160. In FIG. 1, detail 185 shows an example portion of such a memory device, including a portion of a die 160-a that is coupled with a portion of a die 160-b. As described in greater detail in connection with FIGS. 2 thorough 6, the die 160-a may be coupled with the die 160-b using a hybrid-bond interface structure 190 that includes multiple dielectric layers.

FIG. 2 shows an example implementation 200 that supports a hybrid-bond interface structure including multiple dielectric layers in accordance with examples as disclosed herein. As shown in the side section-view of FIG. 2, a portion of the die 160-a is coupled with a portion of the die 160-b. Furthermore, and as part of implementation 200, the die 160-a and the die 160-b are coupled using the hybrid-bond interface structure 190-a.

As shown in FIG. 2, the die 160-a includes a dielectric layer 205-a (e.g., an inter-layer dielectric (ILD)). In some examples, the dielectric layer 205-a may be a “low-k” dielectric layer, and have a dielectric constant (e.g., a k-value) that is less than an approximate k-value of silicon dioxide (e.g., less than around 3.9 in some cases). The dielectric layer 205-a, with such a dielectric constant, may improve a performance of integrated circuitry included in the die 160-a through reduced parasitic capacitance and/or a reduction in crosstalk.

In some examples, a composition of the dielectric layer 205-a may include a matrix material that is densified (e.g., doped) using impurities. In contrast to another composition that may be intrinsic (e.g., another composition that is undoped and not densified using impurities), such a composition may be more resistant to diffusion of atoms, molecules, and/or ions throughout the dielectric layer 205-a, thereby satisfying a threshold related to leakage and/or electrical shorting in the die 160-a. Additionally, or alternatively, such composition may satisfy a threshold related to a k-value.

As an example of such a composition, and as shown in FIG. 2, the dielectric layer 205-a may include silicon oxycarbide (SiOC) (e.g., a matrix material) that is densified using hydrogen (H) impurities (e.g., dopants). A molecular structure of the dielectric layer 205-a may include interstices 210-a (e.g., spaces, gaps, or voids) having a width W1 (and/or a volume) that is reduced relative to interstices in native silicon oxycarbide (e.g., silicon oxycarbide that is not densified using impurities). In other examples, a composition of the dielectric layer 205-a may include another matrix material (silicon carbide, silicon dioxide, silicon nitride, and/or or another matrix material with suitable dielectric properties, among other examples) Additionally, or alternatively, a composition of the dielectric layer 205-a may be densified using another impurity (boron, aluminum, yttrium, germanium, phosphorous, and or another suitable impurity, among other examples).

As further shown in FIG. 2, a structure in the dielectric layer 205-a includes a bonding pad 215-a (e.g., a die bonding pad or a wafer bonding pad) and an interconnect 220-a (a vertical interconnect access connector, or via). The bonding pad 215-a and/or the interconnect 220-a may include a conductive material having diffusive characteristics. In some examples, the conductive material may include a metal material (copper, gold, platinum, aluminum, or another suitable metal material having diffusive characteristics, among other examples). Additionally, or alternatively, the bonding pad 215-a and/or the interconnect 220-a may include a non-metal material (e.g., graphene, a conductive polymer, or another suitable non-metal material having diffusive characteristics, among other examples).

As further shown in FIG. 2, and in some examples, a diffusion barrier layer 225-a (DBL) may be between the bonding pad 215-a and the dielectric layer 205-a. Additionally, or alternatively, the diffusion barrier layer 225-a may be between the interconnect 220-a and the dielectric layer 205-a. In some examples, the diffusion barrier layer 225-a may include a metal material (titanium, titanium nitride, tantalum or another suitable metal material that is resistant to diffusion, among other examples).

As further shown in FIG. 2, the die 160-b includes the dielectric layer 205-b (e.g., an IDL). In some examples, the dielectric layer 205-b may include a matrix material that is densified (e.g., doped) with impurities to increase a resistance to diffusion and/or satisfy a k-value threshold. In some examples, the dielectric layer 205-b may have a composition that is substantially similar (e.g., a composition having a same matrix material and a same impurity) to that of the dielectric layer 205-a. In other examples, the dielectric layer 205-b may have a composition that is different (e.g., a composition having a different matrix material and/or a different impurity) from that of the dielectric layer 205-a.

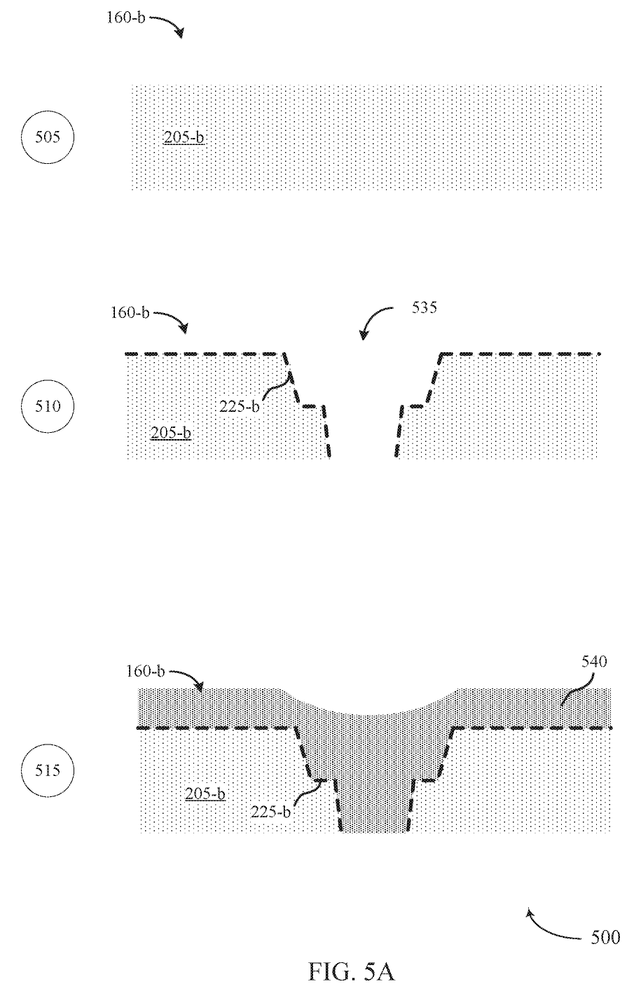

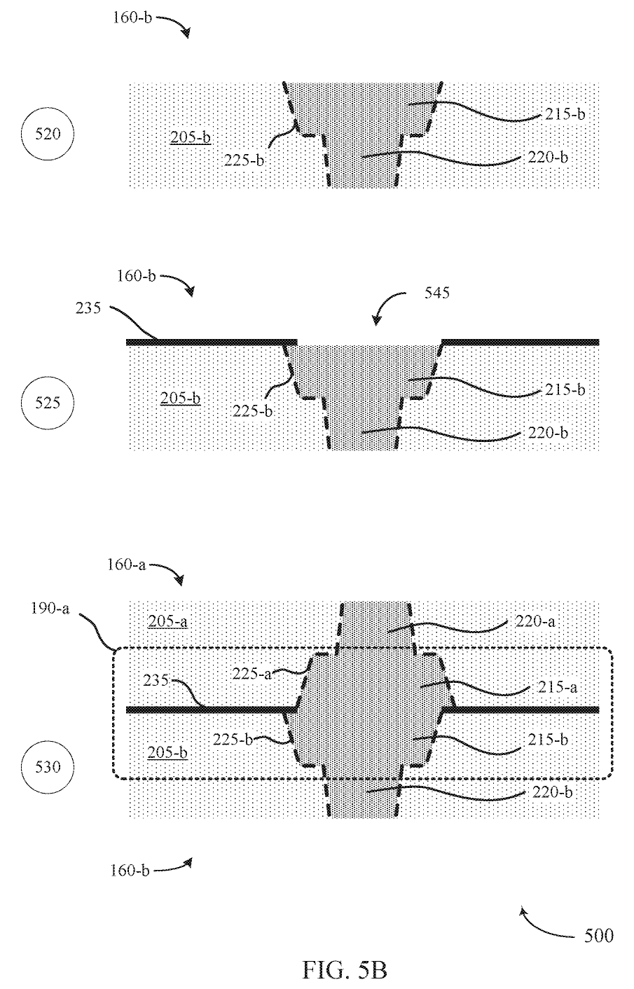

As further shown in FIG. 2, the die 160-b includes the bonding pad 215-b and the interconnect 220-b. In some examples, and as described in greater detail in connection with FIG. 5B, an accuracy and/or a repeatability of a bonding tool that may be used to couple the die 160-b with the die 160-a may result in an offset region 230, in which the bonding pad 215-b and the bonding pad 215-a are laterally offset from one another.

In some examples, the bonding pad 215-b and the interconnect 220-b may include a conductive material that is substantially similar (e.g., a same conductive material having same diffusive characteristics) to that of the bonding pad 215-a and the interconnect 220-a. In other examples, the bonding pad 215-b and the interconnect 220-b may include a conductive material that is different (e.g., a different conductive material having different diffusive characteristics) from that of bonding pad 215-a and the interconnect 220-a.

As further shown in FIG. 2, and in some examples, a diffusion barrier layer 225-b (DBL) may be between the bonding pad 215-b and the dielectric layer 205-b. Additionally, or alternatively, the diffusion barrier layer 225-b may be between the interconnect 220-b and the dielectric layer 205-b.

In some examples, the diffusion barrier layer 225-b may include a metal that is substantially similar (e.g., a same metal material having a same resistance to diffusion) to that of the diffusion barrier layer 225-a. In other examples, the diffusion barrier layer 225-a and the diffusion barrier layer 225-b may include metal materials that are different (e.g., different metal materials having different resistances to diffusion).

As further shown in FIG. 2, a dielectric layer 235 (e.g., a DBL) is between the die 160-a and the die 160-b. In some examples, a composition of the dielectric layer 235 may include a matrix material that is densified (e.g., doped) using impurities. In contrast to another composition that may be intrinsic (e.g., another composition that is undoped and not densified using impurities), such a composition may be resistant to diffusion of atoms, molecules, and/or or ions between the die 160-a and the die 160-b to satisfy a threshold related to leakage and/or electrical shorting. Additionally, or alternatively, such composition may satisfy a threshold related to a k-value.

As an example, and as further shown in FIG. 2, a composition of the dielectric layer 235 may include silicon carbide (SiC) (e.g., a matrix material) that is densified using hydrogen (H) impurities (e.g., dopants). A molecular structure of the dielectric layer 235 may include interstices 210-b (e.g., spaces, gaps, or voids) having a width W2 (and/or a volume) that is reduced relative to interstices in native silicon carbide (e.g., silicon carbide that is not densified using impurities). In other examples, a composition of the dielectric layer 235 may include another matrix material (silicon oxycarbide, silicon dioxide, silicon nitride, silicon carbon nitride, and/or or another matrix material with suitable dielectric properties, among other examples) Additionally, or alternatively, a composition of the dielectric layer 235 may be densified using another impurity (boron, aluminum, yttrium, germanium, phosphorous, and or another suitable impurity, among other examples).

As further shown in FIG. 2, and within the offset region 230, a portion of the dielectric layer 235 may extend over an edge of the bonding pad 215-b. Furthermore, and as shown in FIG. 2, the portion may couple with overlapping surfaces of the dielectric layer 205-a and the bonding pad 215-b. In some examples, the portion may inhibit diffusion and/or migration of atoms, molecules, and/or ions from the bonding pad 215-b into the dielectric layer 205-a.

In some examples, a ratio of a total volume of interstices 210-a included in the dielectric layer 205-a to a total volume of the dielectric layer 205-a may be greater than a ratio of a total volume of interstices 210-b included in the dielectric layer 235 to a total volume of the dielectric layer 235. Additionally, or alternatively, an average size of the interstices 210-a (e.g., the width W1) may be greater than an average size of the interstices 210-b (e.g., the width W2). Said another way and based on dielectric layer 205-a having the greater the ratio and/or the greater average size of interstices, a porosity of the dielectric layer 205-a may be greater than a porosity of the dielectric layer 235.

The hybrid-bond interface structure 190-a of implementation 200 may include the dielectric layer 235, the bonding pad 215-a, and/or the bonding pad 215-b. Additionally, the hybrid-bond interface structure 190-b of implementation 200 may include a portion of the dielectric layer 205-a, a portion of the dielectric layer 205-b, a portion of the diffusion barrier layer 225-a, and/or a portion of the diffusion barrier layer 225-b. The hybrid-bond interface structure 190-a may reduce a likelihood of diffusion of atoms, molecules, and/or ions throughout a stacked die assembly including the die 160-a and the die 160-b thereby reducing a likelihood of electrical shorting and/or leakage within the stacked die assembly to improve a performance of the stacked die assembly.

Other comparative relationships of porosities between the dielectric layer 205-a and the dielectric layer 235 are within the scope of the present disclosure. For example, and based factors that include material selections, impurity selections, and/or desired k-values for electrical functionality of a stacked die assembly including the die 160-a and the die 160-b, the dielectric layer 205-a may have a porosity that is less than, or equal to, a porosity of the dielectric layer 235.

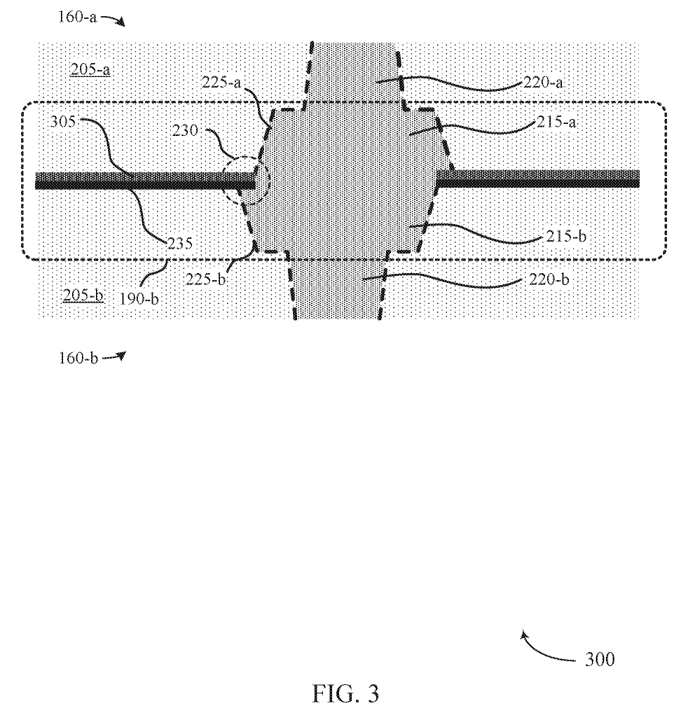

FIG. 3 shows an example implementation 300 that supports a hybrid-bond interface structure including multiple dielectric layers in accordance with examples as disclosed herein. As shown in the side section-view of FIG. 3, a portion of the die 160-a is coupled with a portion of the die 160-b. Furthermore, and as part of implementation 200, the die 160-a and the die 160-b are coupled using the hybrid-bond interface structure 190-b.

As shown in FIG. 3, and as part of implementation 300, the die 160-a may include the dielectric layer 205-a, the bonding pad 215-a, the interconnect 220-a, and the diffusion barrier layer 225-a as described in greater detail in connection with FIG. 2. Furthermore, the die 160-b may include the dielectric layer 205-b, the bonding pad 215-b, the interconnect 220-b, and the diffusion barrier layer 225-b as described in greater detail in connection with FIG. 2.

As further shown in FIG. 3, the hybrid-bond interface structure 190-b may include the bonding pad 215-a, the bonding pad 215-b, and the dielectric layer 235. Additionally, the hybrid-bond interface structure 190-b may include portions of the dielectric layer 205-a, portions of the dielectric layer 205-a, portions of the diffusion barrier layer 225-a, and/or portions of the diffusion barrier layer 225-b. Furthermore, and contrast to the hybrid-bond interface structure 190-a of FIG. 2, the hybrid-bond interface structure 190-b includes a dielectric layer 305 (an additional dielectric layer).

In some examples, the dielectric layer 305 may include substantially similar properties (e.g., a composition having a same matrix material and different impurity) as that of the dielectric layer 235. In other examples, the dielectric layer 305 may have different properties (e.g., a composition having a different matrix material and/or a different impurity) from that of the dielectric layer 305.

The hybrid-bond interface structure 190-b may reduce a likelihood of diffusion of atoms, molecules, and/or ions throughout a stacked die assembly including the die 160-a and the die 160-b, thereby reducing a likelihood of electrical shorting and/or leakage within the stacked die assembly to improve a performance of the stacked die assembly.

As described in connection with FIGS. 1 through 3, and in some examples, an integrated assembly (e.g., the memory device 130, a stacked die assembly) includes a first semiconductor die (e.g., the die 160-a) and a second semiconductor die (e.g., the die 160-b). The first semiconductor die includes a first dielectric layer (e.g., the dielectric layer 205-a) that is densified using first impurities introduced to a first matrix material (e.g., the carbon impurities introduced to the silicon oxycarbide dielectric material). The first semiconductor die includes a conductive bonding pad (e.g., the bonding pad 215-a) in the first dielectric layer. The integrated assembly further includes a second dielectric layer (e.g., the dielectric layer 235) that is densified using second impurities introduced to a second matrix material (e.g., the hydrogen impurities introduced into the silicon carbide matrix material). The second dielectric layer is along a bond interface between the first semiconductor die and the second semiconductor die.

Additionally, or alternatively, and in some examples, a semiconductor system (e.g., the system 100) includes a host system (e.g., the host system 105) and a memory system (e.g., the memory system 110) that is communicatively coupled with the host system. The memory system includes a hybrid-bond interface structure (e.g., the hybrid-bond interface structure 190) that couples a first memory die (e.g., the die 160-a) with a second memory die (e.g., the die 160-b). The hybrid-bond interface structure includes a first conductive bonding pad (e.g., the bonding pad 215-a) in a first dielectric layer (e.g., the dielectric layer 205-a) of the first memory die. The hybrid-bond interface structure includes a second conductive bonding pad (e.g., the bonding pad 215-b) in a second dielectric layer (e.g., the dielectric layer 205-b) of the second memory die, where the second conductive pad is laterally offset from the first bonding pad. The hybrid-bond interface structure includes a third dielectric layer (e.g., the dielectric layer 235) between the first dielectric layer and the second dielectric layer, where the third dielectric layer extends across an edge of the second conductive bonding pad and over a portion of the second bonding pad.

In these ways, a hybrid-bond interface structure may reduce a likelihood of diffusion and/or migration of atoms, molecules, and/or ions from bonding pads into layers of a stacked die assembly, thereby reducing a likelihood of electrical shorting and/or leakage within the stacked die assembly. By reducing the likelihood of electrical shorting, a performance of the stacked die assembly, or a system including the stacked die assembly, may be improved.

Furthermore, and although described in the context of a stacked die assembly including a semiconductor die that is a NAND memory die (e.g., the die 160-a and/or die 160-b), other types of semiconductor dies are within the scope of the present disclosure. For example, one or more aspects of the hybrid-bond interface structure 190-a and/or the hybrid-bond interface structure 190-b may be applicable to another stacked die assembly including a DRAM memory die, a processor die, an optoelectronic die, a radio frequency (RF) communication die, or an application specific integrated circuit (ASIC) die, among other examples.

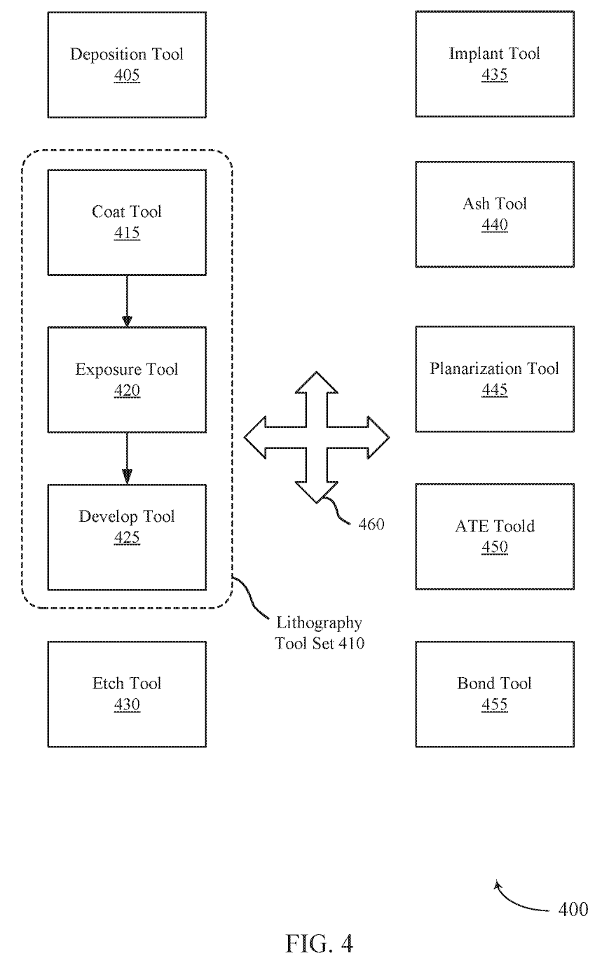

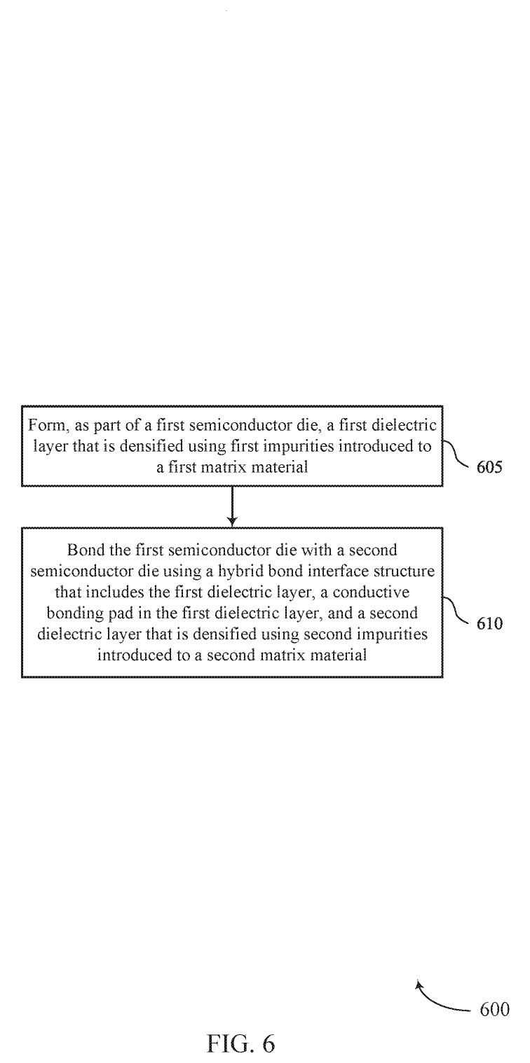

FIG. 4 shows an example manufacturing system 400 that supports a hybrid-bond interface structure including multiple dielectric layers in accordance with examples as disclosed herein. The manufacturing system 400, or portions thereof, may be located in a semiconductor foundry (e.g., a wafer foundry). In some examples, portions of the manufacturing system 400 may be part of front end of line (FEOL) operations used to fabricate active integrated circuitry (e.g., transistors, diodes, memory cells, and/or other active integrated circuitry) on a semiconductive substrate (e.g., a silicon wafer). Additionally, or alternatively, and in some examples, portions of the manufacturing system 400 may be part of back end of line (BEOL) operation used to fabricate interconnect structures (e.g., conductive traces, redistribution layers, vertical interconnect access structures (vias), and/or other interconnect structures) that electrically connect the active integrated circuitry. Furthermore, in some examples and as described in greater detail in connection with FIGS. 5A through 6, the manufacturing system 400 may be used to fabricate one or more features related to a hybrid-bond interface structure (e.g., the hybrid-bond interface structure 190).

As shown in FIG. 4, the manufacturing system 400 may include a deposition tool 405. In some examples, the deposition tool 405 may be used to form a layer of material (e.g., a layer of a semiconductive material, a layer of a conductive material, and/or a layer of a dielectric material) over and/or on a semiconductive substrate (e.g., a silicon wafer). To form the layer of the material, the deposition tool 405 may use a chemical vapor deposition (CVD) technique, a physical vapor deposition (PVD) technique, an oxidation technique, an epitaxial growth technique, or another suitable deposition technique, among other examples.

As further shown in FIG. 4, the manufacturing system 400 may include a lithography tool set 410. The lithography tool set 410 may include a coat tool 415, an exposure tool 420, and/or a develop tool 425. In some examples, the lithography tool set 410 may be used to form a patterned layer of photoresist over and/or on a layer of material formed by the deposition tool 405. In some examples, the patterned layer of photoresist may be temporary and may be used as a template to form features in the layer of material formed by the deposition tool 405.

In some examples, the coat tool 415 may be used to form a layer of photoresist (e.g., a layer of material that changes properties when irradiated) over and/or on a layer of material formed by the deposition tool 405. In some examples, and to form the layer of photoresist, the coat tool 415 may use a spin coating technique that dispenses a controlled amount of liquid photoresist onto the layer of material and spin a semiconductive substrate carrying the layer of material to uniformly distribute the liquid photoresist and form the layer of photoresist. Additionally, or alternatively, and in some examples, the coat tool 415 may heat the layer of photoresist to cure the layer of photoresist.

In some examples, the exposure tool 420 may irradiate portions of a layer of photoresist. To irradiate the portions, the exposure tool 420 may generate electromagnetic waves (ultraviolet (UV) light waves, extreme ultraviolet (EUV) light waves, electron beams, or x-ray beams) and project the electromagnetic waves through a photomask (e.g., a reticle) to irradiate the portions. In some examples, the photomask may include a patterned layer of opaque material that replicates the portions, where the patterned layer is formed on a quartz or glass substrate that is transparent to the electromagnetic waves.

In some examples, the develop tool 425 may be used to develop a layer of photoresist to form a patterned layer of photoresist (e.g., a template). As an example, and in a case where the layer of photoresist includes a “positive” photoresist material, portions of the layer of photoresist that are irradiated may be soluble to a developer solution and the develop tool 425 may dispense the developer solution to remove the irradiated portions. As another example, and in a case where the layer of photoresist includes a “negative” photoresist material, portions of the layer that are irradiated may be insoluble to a developer solution and the develop tool 425 may dispense the developer solution to remove portions of the layer of photoresist that are not radiated.

As further shown in FIG. 4, the manufacturing system 400 may include an etch tool 430. In some examples, the etch tool 430 may be used to remove portions of one or more layers of material formed by the deposition tool 405. In some examples, removing the portions may include removing and/or exhuming the portions through a patterned layer of photoresist (e.g., a template) formed by the lithography tool set 410. To remove the portions, the etch tool 430 may use a wet etching technique, a dry etching technique, an ion beam etching technique, a laser etching technique, a chemical etching technique, or another suitable etching technique, among other examples.

As further shown in FIG. 4, the manufacturing system 400 may include an implant tool 435. In some examples, the implant tool 435 may be used to implant impurities (e.g., dopants) into a layer of material formed by the deposition tool. In some examples, implanting the impurities may modify electrical properties of the layer of material and/or change a lattice structure to modify a mechanical property of the layer of material. To implant the impurities, the implant tool 435 may use an ion implanting technique, a plasma doping technique, a cluster/molecular implanting technique, a laser-assisted implanting technique, a beamline implanting technique, or another suitable implanting technique, among other examples.

As further shown in FIG. 4, the manufacturing system 400 may include an ash tool 440. In some examples, the ash tool 440 may be used to remove a patterned layer of photoresist. To remove the patterned layer of photoresist, the ash tool 440 may use a plasma-based oxidizing technique or another suitable ashing technique, among other examples.

As further shown in FIG. 4, the manufacturing system 400 may include a planarization tool 445. In some examples, the planarization tool 445 may be used to planarize a layer of material formed by the deposition tool 405. In some examples, planarizing the layer of material may remove a portion of the layer of material, reduce a thickness of the layer of material, polish the layer of material, and/or improve a uniformity of a thickness of the layer of material. To planarize the layer of material the planarization tool 445 may use a chemical/mechanical planarization (CMP) technique or another suitable planarization technique, among other examples.

As further shown in FIG. 4, the manufacturing system 400 may include an automated test equipment (ATE) tool 450. In some examples, the ATE tool 450 may be used to test (e.g., electrically test) or more features formed from layers of material on a semiconductive substrate. Testing may include testing one or more parametric parameters (a drive current, a resistivity, or a voltage) that may be indicative of a critical dimension (a line width, a thickness, or a surface roughness, among other examples) of a feature. Additionally, or alternatively, and in some examples, testing may include testing a quality (e.g., a timing, frequency, and/or electrical performance) related to a functionality of active circuitry formed on the semiconductive substrate. Additionally, or alternatively, and in some examples, testing may include stressing the active circuitry to determine a reliability of the active circuitry. To perform the testing, the ATE tool 450 may use a contact probe testing technique or another suitable testing technique, among other examples.

As further shown in FIG. 4, the manufacturing system may include a bond tool 455. In some examples, the bond tool 455 may be used to couple two semiconductive substrates (including active circuitry) along a bond interface. The bond interface may include dielectric-to-dielectric bonds, metal-to-metal bonds, and/or a combination thereof (e.g., the bond interface may be a hybrid-bond interface). To couple the two semiconductive substrates, the bond tool 455 may use a thermal compression technique, an anodic bonding technique, an adhesive bonding technique, a fusion bonding technique, or another suitable bonding technique, among other examples.

Each tool of the manufacturing system 400 may include mechanics, circuitry, logic, means, or instructions (e.g., a non-transitory computer-readable medium storing instructions executable by a processor), or any combination thereof to perform a designated manufacturing operation. During a series of manufacturing operations used to form a feature (e.g., form a feature of a memory device or another semiconductive device), a progression 460 (e.g., a sequence and/or an ordered use) amongst the tools may be based on a design and/or a structure of the feature. In some examples, the progression 460 may rely on an entirety of the manufacturing system 400 (e.g., rely on each tool being used). Alternatively, and in some examples, the progression 460 may rely on a portion of the manufacturing system 400 (e.g., rely on a subset of the tools being used).

FIGS. 5A and 5B show stages of example manufacturing process 500 that supports a hybrid-bond interface structure (e.g., the hybrid-bond interface structure 190) including multiple dielectric layers in accordance with examples as disclosed herein. The example manufacturing process 500 may use one or more manufacturing tools as described in connection with FIG. 4 to fabricate a stacked die assembly including the hybrid-bond interface structure and is described using example stages 505 through 530.

As shown in FIG. 5A, and at stage 505, the manufacturing process 500 may include forming the dielectric layer 205-b as part of the die 160-b. In some examples, and at stage 505, forming the dielectric layer 205-b may include a deposition tool (e.g., the deposition tool 405) performing an in-situ deposition operation that deposits a matrix material (e.g., silicon oxycarbide) and impurities (e.g., hydrogen dopants) simultaneously. In some examples, and at stage 505, forming the dielectric layer 205-b may include a deposition tool depositing a matrix material and an implant tool (e.g., the implant tool 435) implanting impurities in separate operations.

As further shown in FIG. 5A, and at stage 510, the manufacturing process 500 may include forming a cavity 535 in the dielectric layer 205-b and the diffusion barrier layer 225-b over and/or along contours of the cavity 535. In some examples, and at stage 510, forming the cavity 535 may include a lithography tool set (e.g., the lithography tool set 410) and an etch tool (e.g., the etch tool 430) performing a series of operations that form one or more patterned layers of photoresist material over and/or on the dielectric layer 205-b and remove portions of the dielectric layer 205-b using the one or more patterned layers of photoresist materials as templates. Furthermore, and at stage 510, forming the diffusion barrier layer 225-b may include a deposition tool (e.g., the deposition tool 405) performing a deposition operation that forms the diffusion barrier layer 225-b over and/or along contours of the cavity 535 and along a top surface of the dielectric layer 205-b.

As further shown in FIG. 5A, and at stage 515, the manufacturing process 500 may include forming layer of conductive material 540 that fills the cavity 535 and is over and/or along surfaces of the diffusion barrier layer 225-b. In some examples, and at stage 515, forming the layer of conductive material 540 may include a deposition tool (e.g., the deposition tool 405) performing a deposition operation that deposits the layer of conductive material 540 in the cavity and over and/or along surfaces of the diffusion barrier layer 225-b.

As shown in FIG. 5B, and at stage 520, the manufacturing process 500 may include removing portions of the layer of conductive material 540 and portions of the diffusion barrier layer 225-b along the top surface of the dielectric layer 205-b, effective to form the bonding pad 215-b and the interconnect 220-b. In some examples, and at stage 520, removing the portions may include a planarization tool (e.g., the planarization tool 445) performing planarization operation that removes the portions. In some examples, the planarization operation, in combination with the deposition operation described in connection with stage 515, may be part of a damascene operation.

As further shown in FIG. 5B, and at stage 525, the manufacturing process 500 may include forming the dielectric layer 235 over and/or on the dielectric layer 205-b. In some examples, and at stage 525, forming the dielectric layer 205-b may include a deposition tool (e.g., the deposition tool 405) performing an in-situ deposition operation that deposits a matrix material (e.g., silicon carbide) and impurities (e.g., hydrogen dopants) simultaneously. In some examples, and at stage 505, forming the dielectric layer 205-b may include a deposition tool depositing a matrix material and an implant tool (e.g., the implant tool 435) implanting impurities in separate operations. Furthermore, and in some examples at stage 525, forming the dielectric layer 235 include a lithography tool set (e.g., the lithography tool set 410) and an etch tool (e.g., the etch tool 430) performing a series of operations that form an opening 545 in the dielectric layer 235 to expose a top surfaces of the bonding pad 215-b. In some examples, the opening 545 may be configured such that a portion of the dielectric layer 235 extends across (e.g., overlaps) an edge of the bonding pad 215-b to compensate for potential misalignment with another bonding pad during a subsequent bonding operation that joins the die 160-b with another die (e.g., the die 160-b).

As further shown in FIG. 5B, and at stage 530, the manufacturing process 500 may include bonding the die 160-b with the die 160-a. In some examples, and at stage 530, bonding the die 160-b with the die 160-a may include a bond tool (e.g., the bond tool 455) performing a bonding operation that incorporates elements of the hybrid-bond interface structure 190-a.

FIG. 6 shows a flowchart illustrating a method 600 that supports a hybrid-bond interface structure including multiple dielectric layers in accordance with examples as disclosed herein. The operations of method 600 may be implemented by one or more semiconductor manufacturing tools of a manufacturing system as described herein. For example, the operations of method 600 may be performed by one or more semiconductor manufacturing tools of a manufacturing system as described with reference to FIG. 4 (e.g., one or more semiconductor manufacturing tools of the manufacturing system 400). In some examples, a semiconductor manufacturing tool may execute a set of instructions to control the functional elements of the semiconductor manufacturing tool to perform the described functions. Additionally, or alternatively, a semiconductor manufacturing tool may perform aspects of the described functions using special-purpose hardware.

At 605, the method may include forming, as part of a first semiconductor die, a first dielectric layer that is densified using first impurities introduced to a first matrix material. In some examples, aspects of the operations of 605 may be performed by tools of a manufacturing system. For example, a deposition tool (e.g., the deposition tool 405 as described in connection with FIG. 4) may be used to deposit the first dielectric layer.

At 610, the method may include bonding the first semiconductor die with a second semiconductor die using a hybrid-bond interface structure that includes the first dielectric layer, a conductive bonding pad in the first dielectric layer, and a second dielectric layer that is densified using second impurities introduced to a second matrix material. In some examples, aspects of the operations of 610 may be performed by tools of a manufacturing system. For example, a bonding tool (e.g., the bond tool 455 as described in connection with FIG. 4) may be used to bond the first semiconductor die with the semiconductor die.

In some examples, one or more tools of a manufacturing system described herein (e.g., one or more tools of the manufacturing system 400) may perform a method or methods, such as the method 600. The tools may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming, as part of a first semiconductor die, a first dielectric layer that is densified using first impurities introduced to a first matrix material and bonding the first semiconductor die with a second semiconductor die using a hybrid-bond interface structure that includes the first dielectric layer, a conductive bonding pad in the first dielectric layer, and a second dielectric layer that is densified using second impurities introduced to a second matrix material.

Aspect 2: The method, apparatus, or non-transitory computer-readable medium of aspect 1, where bonding the first semiconductor die with the second semiconductor die includes operations, features, circuitry, logic, means, or instructions, or any combination thereof for bonding a first semiconductor wafer including the first semiconductor die with a second semiconductor wafer including the second semiconductor die.

Aspect 3: The method, apparatus, or non-transitory computer-readable medium of any of aspects 1 through 2, where bonding the first semiconductor die with the second semiconductor die includes operations, features, circuitry, logic, means, or instructions, or any combination thereof for bonding the first semiconductor die in a discrete form with the second semiconductor die in a discrete form.

Aspect 4: The method, apparatus, or non-transitory computer-readable medium of any of aspects 1 through 3, where forming the first dielectric layer includes operations, features, circuitry, logic, means, or instructions, or any combination thereof for using a deposition operation to deposit the first matrix material and using an implant operation that is separate from the deposition operation to implant the first impurities into the first matrix material.

Aspect 5: The method, apparatus, or non-transitory computer-readable medium of any of aspects 1 through 4, where forming the first dielectric layer includes operations, features, circuitry, logic, means, or instructions, or any combination thereof for using an in-situ deposition operation to deposit the first matrix material and the first impurities simultaneously.

Aspect 6: The method, apparatus, or non-transitory computer-readable medium of any of aspects 1 through 5, further including operations, features, circuitry, logic, means, or instructions, or any combination thereof for forming the conductive bonding pad in the first dielectric layer using a damascene operation.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 7: An integrated assembly, including: a first semiconductor die, including: a first dielectric layer that is densified using first impurities introduced to a first matrix material; and a conductive bonding pad in the first dielectric layer; a second semiconductor die including a second dielectric layer that is densified using second impurities introduced to a second matrix material and is along a bond interface between the first semiconductor die and the second semiconductor die.

Aspect 8: The integrated assembly of aspect 7, where a portion of the second dielectric layer extends across a portion of a second conductive bonding pad in the second semiconductor die.

Aspect 9: The integrated assembly of any of aspects 7 through 8, where the first matrix material and the second matrix material are a same matrix material.

Aspect 10: The integrated assembly of any of aspects 7 through 9, where the first matrix material and the second matrix material are different matrix materials.

Aspect 11: The integrated assembly of any of aspects 7 through 10, where a first ratio of a total volume of first interstices included in the first dielectric layer to a total volume of the first dielectric layer is greater than a second ratio of a total volume of second interstices included in the second dielectric layer to a total volume of the second dielectric layer.

Aspect 12: The integrated assembly of any of aspects 7 through 11, where the first dielectric layer and the second dielectric layer each include: a dielectric constant that is less than or equal to an approximate dielectric constant of silicon dioxide.

Aspect 13: The integrated assembly of any of aspects 7 through 12, where the first semiconductor die further includes: a diffusion barrier layer between the first conductive bonding pad and the first dielectric layer.

An apparatus is described. The following provides an overview of aspects of the apparatus as described herein:

Aspect 14: A semiconductor system, including: a host system; and a memory system communicatively coupled with the host system, including: a hybrid-bond interface structure that couples a first memory die with a second memory die, including: a first conductive bonding pad in a first dielectric layer of the first memory die; a second conductive bonding pad in a second dielectric layer of the second memory die, where the second conductive bonding pad is laterally offset from the first conductive bonding pad; and a third dielectric layer between the first dielectric layer and the second dielectric layer, where the third dielectric layer includes a portion that extends across an edge of the second conductive bonding pad and over a portion of the second conductive bonding pad.

Aspect 15: The semiconductor system of aspect 14, where a portion of the third dielectric layer directly couples with overlapping surfaces of the second conductive bonding pad and the first dielectric layer.

Aspect 16: The semiconductor system of any of aspects 14 through 15, where the hybrid-bond interface structure further includes: a fourth dielectric layer between the third dielectric layer and the second dielectric layer, where fourth dielectric layer extends across the edge of the second conductive bonding pad and over the portion of the second conductive bonding pad.

Aspect 17: The semiconductor system of aspect 16, where a portion of the fourth dielectric layer directly couples with overlapping surfaces of the second conductive bonding pad and the third dielectric layer.

Aspect 18: The semiconductor system of any of aspects 16 through 17, where the first dielectric layer, the second dielectric layer, the third dielectric layer, and the fourth dielectric layer each include: a dielectric constant that is less than or equal to an approximate dielectric constant of silicon dioxide.

Aspect 19: The semiconductor system of any of aspects 16 through 18, where: the first dielectric layer is densified using first impurities introduced to a first matrix material; the second dielectric layer is densified using second impurities introduced to a second matrix material; the third dielectric layer is densified using third impurities introduced into a third matrix material; and the fourth dielectric layer is densified using fourth impurities introduced into a fourth matrix material.

Aspect 20: The semiconductor system of aspect 19, where: the first matrix material and the second matrix material are a same matrix material; and the third matrix material and the fourth matrix material are a same matrix material.

Aspect 21: The semiconductor system of any of aspects 19 through 20, where a first average size of first interstices included in the first dielectric layer is greater than a second average size of second interstices included in the third dielectric layer.

Aspect 22: The semiconductor system of any of aspects 19 through 21, where a first average size of first interstices included in the second dielectric layer is greater than a second average size of second interstices included in the fourth dielectric layer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the term “substantially” means that the modified characteristic (e.g., a verb or adjective modified by the term substantially) need not be absolute but is close enough to achieve the advantages of the characteristic.

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An integrated assembly, comprising:
a first semiconductor die, comprising:
a first dielectric layer that is densified using first impurities introduced to a first matrix material; and
a conductive bonding pad in the first dielectric layer; and
a second semiconductor die comprising:
a second dielectric layer that is densified using second impurities introduced to a second matrix material and is along a bond interface between the first semiconductor die and the second semiconductor die.

2. The integrated assembly of claim 1, wherein a portion of the second dielectric layer extends across a portion a second conductive bonding pad in the second semiconductor die.

3. The integrated assembly of claim 1, wherein the first matrix material and the second matrix material are a same matrix material.

4. The integrated assembly of claim 1, wherein the first matrix material and the second matrix material are different matrix materials.

5. The integrated assembly of claim 1, wherein a first ratio of a total volume of first interstices included in the first dielectric layer to a total volume of the first dielectric layer is greater than a second ratio of a total volume of second interstices included in the second dielectric layer to a total volume of the second dielectric layer.

6. The integrated assembly of claim 1, wherein the first dielectric layer and the second dielectric layer each comprise:
a dielectric constant that is less than or equal to an approximate dielectric constant of silicon dioxide.

7. The integrated assembly of claim 1, wherein the first semiconductor die further comprises:
a diffusion barrier layer between the conductive bonding pad and the first dielectric layer.

8. A semiconductor system, comprising:
a host system; and
a memory system communicatively coupled with the host system, comprising:
a hybrid-bond interface structure that couples a first memory die with a second memory die, comprising:
a first conductive bonding pad in a first dielectric layer of the first memory die;
a second conductive bonding pad in a second dielectric layer of the second memory die, wherein the second conductive bonding pad is laterally offset from the first conductive bonding pad; and
a third dielectric layer between the first dielectric layer and the second dielectric layer, wherein the third dielectric layer includes a portion that extends across an edge of the second conductive bonding pad and over a portion of the second conductive bonding pad.

9. The semiconductor system of claim 8, wherein a portion of the third dielectric layer directly couples with overlapping surfaces of the second conductive bonding pad and the first dielectric layer.

10. The semiconductor system of claim 8, wherein the hybrid-bond interface structure further comprises:
a fourth dielectric layer between the third dielectric layer and the second dielectric layer,
wherein fourth dielectric layer extends across the edge of the second conductive bonding pad and over the portion of the second conductive bonding pad.

11. The semiconductor system of claim 10, wherein a portion of the fourth dielectric layer directly couples with overlapping surfaces of the second conductive bonding pad and the third dielectric layer.

12. The semiconductor system of claim 10, wherein the first dielectric layer, the second dielectric layer, the third dielectric layer, and the fourth dielectric layer each comprise:
a dielectric constant that is less than or equal to an approximate dielectric constant of silicon dioxide.

13. The semiconductor system of claim 10, wherein:
the first dielectric layer is densified using first impurities introduced to a first matrix material;
the second dielectric layer is densified using second impurities introduced to a second matrix material;
the third dielectric layer is densified using third impurities introduced into a third matrix material; and
the fourth dielectric layer is densified using fourth impurities introduced into a fourth matrix material.

14. The semiconductor system of claim 13, wherein:
the first matrix material and the second matrix material are a same matrix material; and
the third matrix material and the fourth matrix material are a same matrix material.

15. The semiconductor system of claim 13, wherein a first average size of first interstices included in the first dielectric layer is greater than a second average size of second interstices included in the third dielectric layer.

16. The semiconductor system of claim 13, wherein a first average size of first interstices included in the second dielectric layer is greater than a second average size of second interstices included in the fourth dielectric layer.

17. A method, comprising:
forming, as part of a first semiconductor die, a first dielectric layer that is densified using first impurities introduced to a first matrix material; and
bonding the first semiconductor die with a second semiconductor die using a hybrid-bond interface structure that includes the first dielectric layer, a conductive bonding pad in the first dielectric layer, and a second dielectric layer that is densified using second impurities introduced to a second matrix material.

18. The method of claim 17, wherein bonding the first semiconductor die with the second semiconductor die comprises:
bonding a first semiconductor wafer including the first semiconductor die with a second semiconductor wafer including the second semiconductor die.

19. The method of claim 17, wherein bonding the first semiconductor die with the second semiconductor die comprises:
bonding the first semiconductor die in a discrete form with the second semiconductor die in a discrete form.

20. The method of claim 17, wherein forming the first dielectric layer comprises:
using a deposition operation to deposit the first matrix material; and
using an implant operation that is separate from the deposition operation to implant the first impurities into the first matrix material.

21. The method of claim 17, wherein forming the first dielectric layer comprises:
using an in-situ deposition operation to deposit the first matrix material and the first impurities simultaneously.

22. The method of claim 17, further comprising:
forming the conductive bonding pad in the first dielectric layer using a damascene operation.
